(19) United States
(12) Patent Application Publication
(10) Pub. No.: US 2012/0138120 A1
(43) Pub. Date: Jun. 7, 2012

(54) DIMENSIONAL SOLAR CELLS AND SOLAR PANELS

(76) Inventor: Mario Fernandez, Edina, MN (US)

(21) Appl. No.: 13/312,084

(22) Filed: Dec. 6, 2011

Related U.S. Application Data
(60) Provisional application No. 61/420,586, filed on Dec. 7, 2010.

(51) Int. Cl. H01L 31/052

(52) U.S. Cl. 136/246

(57) ABSTRACT

A dimension solar panel including a plurality of solar cells that are arranged in a spacing. The solar panel has a convex configuration so that the solar panel comprises at least 10 percent more solar cells than a flat solar panel with a plurality of solar cells that are arranged in the spacing.

### REFERENCE TO RELATED APPLICATION

This application claims priority to U.S. Application No. 61/420,586, which was filed on Dec. 7, 2010, the contents of which are incorporated herein by reference.

### FIELD OF THE INVENTION

The invention relates generally to solar power. More particularly, the invention relates to dimension solar cells and panels.

### BACKGROUND OF THE INVENTION

Solar energy is viewed as an attractive alternative to energy obtained from other sources because solar energy is produced without using fossil fuels, without the production of carbon dioxide and considered to be a sustainable energy.

While there have been significant gains in the efficiency at which solar energy may be generated, there continues to be research into ways to enhance the efficiency at which solar energy may be generated. For example, research has focused on how to generate more solar energy for a given area.

An embodiment of the invention is directed to a dimensional solar cell and panel that includes a plurality of solar cells that have multiple convex channels and are arranged in a spacing similar to standard flat cells and panels. The solar cells are also arranged in multiple numbers, such as 18 cells, to form a solar panel. The panel may have multiple cells as described, or have a single large cell convex configuration so that both the solar cells and the solar panels comprises at least 30 percent more surface area than a flat solar panel with a plurality of solar cells that are arranged in the spacing.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is an end view of a dimensional solar panel according to an embodiment of the invention.

FIG. 2 is a perspective view of a dimensional solar panel according to another embodiment of the invention.

FIG. 2 is a perspective view of a dimensional solar cell according to another embodiment of the invention.

FIG. 3 is a perspective view of an array of dimensional solar cells forming a solar panel of FIG. 2.

FIG. 4 is a perspective view of a dimensional solar cell according to another embodiment of the invention.

FIG. 5 is a perspective view of a row of the dimensional solar cells of FIG. 4.

FIG. 6 is a perspective view of an array of dimensional solar cells forming a solar panel of FIG. 4 that are arranged in a plurality of rows and a plurality of columns.

FIG. 7 is a side view of a dimensional solar cell according to another embodiment of the invention.

FIG. 8 is a side view of a dimensional solar cell according to another embodiment of the invention.

FIG. 9 is a side view of a dimensional solar cell according to another embodiment of the invention.

FIG. 10 is a side view of a dimensional solar cell according to another embodiment of the invention.

FIG. 11 is a top perspective view of a plurality of dimensional solar panels and or cells in an array that follows the shape of so called “Spanish style tiles”.

FIG. 12 is a perspective view of the dimensional solar panel attached to a mounting structure.

### DETAILED DESCRIPTION OF THE PREFERRED EMBODIMENTS

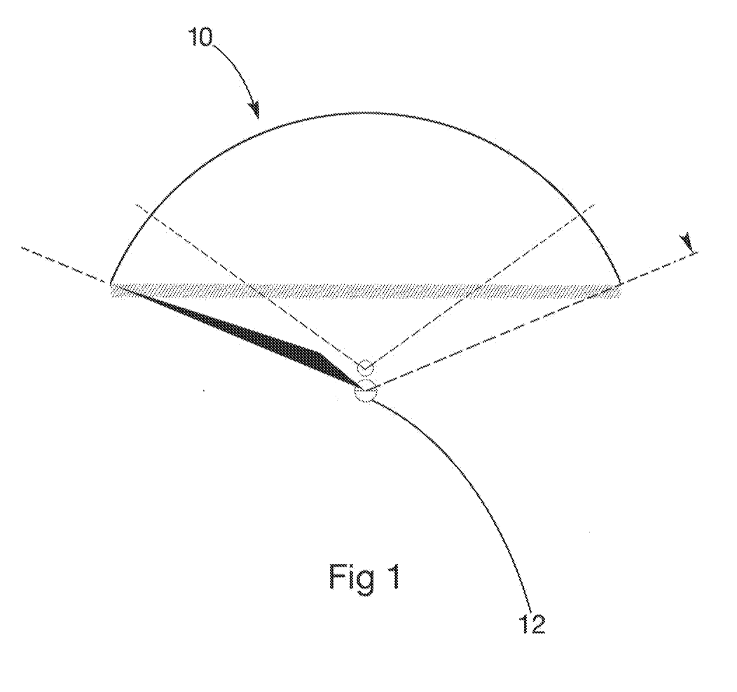

An embodiment of the invention relates to enhancing the performance of solar systems without increasing the size of the envelope or footprint of the solar cell or solar panel. In contrast to typical solar panels that are substantially flat, the dimensional solar cells or panels according to this invention have a convex configuration, as illustrated at 10 in FIG. 1.

The essence of the invention applies to either single solar cells or large solar panels where either the solar cells or the solar panels follow the concept described herein of having a dimensional structure that allows the surface of the solar cell or the solar panel to be larger than the footprint by virtue of its three-dimensional characteristics.

The invention is directed at solar cells that are used as special purpose cells (such as battery chargers or to power specific appliances) and or utilized in solar panels assemblies. These assemblies can be rotated and or turned to follow the location of the sun with the use of so called trackers. This proviso will minimize any potential of shadows created through positioning of panels and/or from shape interference and therefore the complete surface will be able to absorb the totality of the sun photons, either from direct rays and/or those dispersed in the sky and/or reflected from the surrounding objects and/or ground.

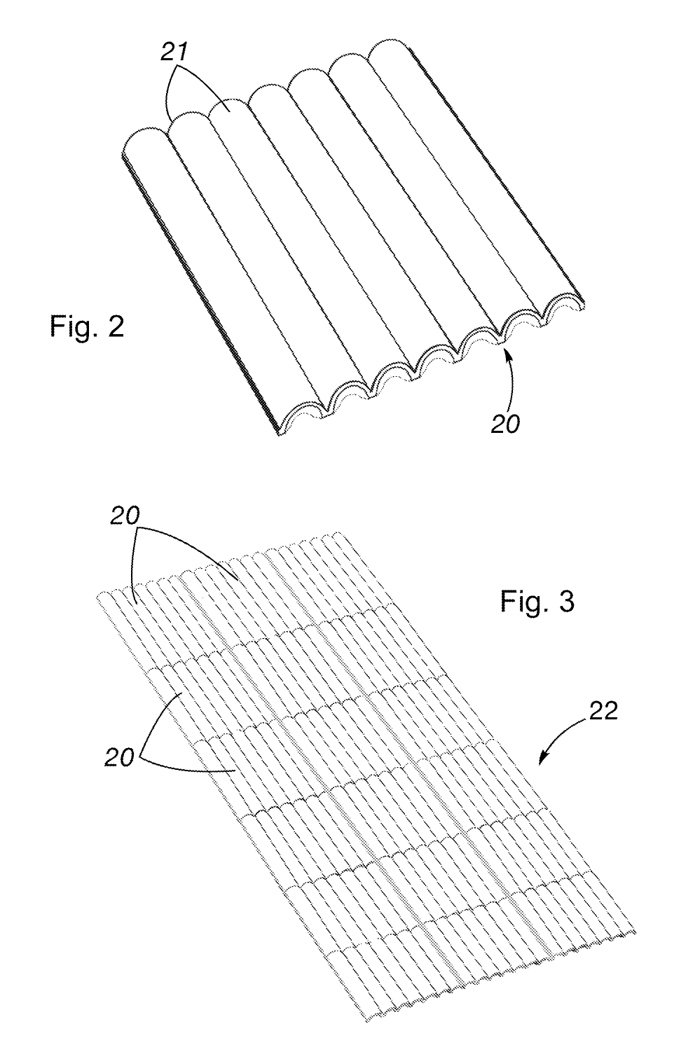

The rays of the sun are not like laser beam types and, therefore, they have the ability to diffuse and expand across each of the seven veins or channels (shown in cell—FIG. 2—or in cells forming a panel as shown in FIG. 3). Because of the low profile (such as ⅜ of an inch) that make up a dimension cell, potential shadows may form in some small fashion at the lowest positions of the sun such as sunrise and sunset.

The dimensional partial solar cell or panel shape 10 has a surface area that is at least about 30 percent greater than the surface area of the flat solar cells or panels. In other embodiments, the dimensional solar cell or shape of panel 10 has a surface area that is at least about 35 to 40 percent greater than the surface area of the flat solar panels.

For example, a flat solar cell equivalent to a flat cell of 200 mm may have a total surface area of solar cells of about 62.25 square inches while the dimensional solar cell 10 may have a surface area of solar cells of about 85.38 square inches. This additional surface area translates into a greater amount of power absorbing area that may be generated by the dimensional solar panel 10. The increase in surface area of the dimensional solar panel 10 may be directly related to the amount of power that may be generated by the dimensional solar panel 10.

While further increasing the height of the dimensional solar panel 10 could increase the surface area of the dimensional solar panel; such additional increase may actually decrease the amount of power produced by the dimensional solar cell or panel because a potential shadow may be created.

Geometry of the Solar cells and Panels: The solar panel receives solar energy over an angle of greater than about 90°. This angle is calculated from an axis that is about 8.5 inches below a base of the solar panel when the solar panel has a width of about 24 inches. An upper edge of the solar panel may be about 8 inches above the base of the solar panel when the solar panel has a width of about 24 inches.

Each individual row or vein of a dimension solar cell receives solar energy over and angle greater than 90 degrees. The entire solar cell also receives solar energy over an angle of greater than about 90 degrees. In the embodiment shown in solar cell FIG. 2, this angle is calculated from an axis that is about 0.243 inches below a base of the solar cell when each vein or channel of the solar cell has a width of about 1.125 inches. An upper edge of the solar panel may be about 0.375 inches above the base of the solar cell when the solar cell has a width of about 7.87 inches.

The arched rows allow solar energy to be impinged thereon over an angle of greater than about 90°. In certain embodiments the angle is between about 105° and about 115°. Using the arched configuration for the solar panels enables the amount of solar cells in a given region to be increased by up to about 30% or more when compared to a solar panel having solar cells mounted substantially flat thereon.

The geometry and order of this arc measurement takes into consideration the additional 16.7 degrees of area available to each side of the central segment [comprised of the 110 degrees angle and the sidebars]. The total effective arc is 143.6 degrees of dimensional linear space.

The solar panels may be formed in a variety of sizes. To increase the efficiency of the manufacturing process, the solar panels may be formed in standardized sizes. One such standardized size has a width of about 24 inches and a length of about 48 inches.

A variety of techniques could be used for fabricating the solar panels. One such suitable technique is die cutting a backing material having the desired shape. Thereafter, the solar cells may be placed on the backing material. A variety of techniques may be used for attaching the solar cells to the solar panels. Suitable techniques may depend on factors such as the material from which the base and solar cells are fabricated as well as the conditions under which the solar panels are intended to be used.

The dimensional solar panels may utilize a variety of techniques for generating electricity. Examples of such techniques include flexible photovoltaic, monocrystalline or single crystal silicon, multicrystalline silicon, polycrystalline silicon, amorphous silicon, cast cell components and thin film or printed plastic elements.

In one configuration of the dimensional solar panel 20 includes a plurality of relatively small elevated regions, as illustrated in FIG. 2. Depending on factors such as the amount of energy that is desired to be generated by the dimensional solar panel 20, the dimensional solar panel 20 may be used by itself.

An array may be formed by placing the dimensional solar panels 20 in a plurality of rows and a plurality of columns, as illustrated in FIG. 3. This configuration could be identified as a slim design because a distance between the upper and lower surfaces is less than this distance in other configurations.

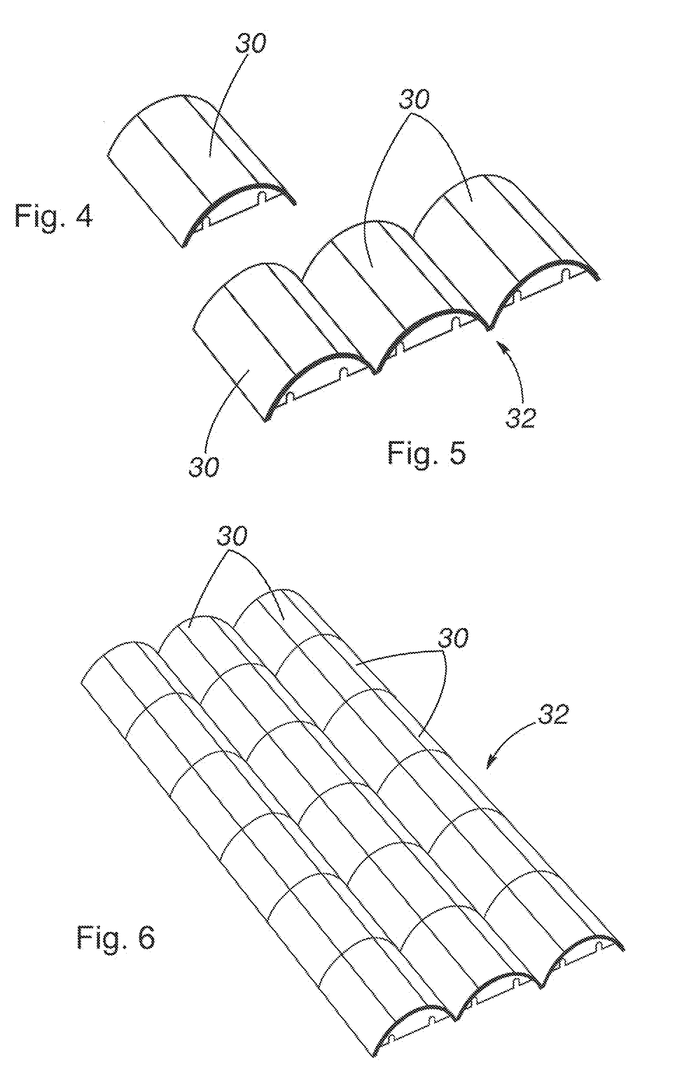

In another configuration of the invention, each of the dimensional solar panels 30 includes one elevated region, as illustrated in FIG. 4. The dimensional solar panels 30 may be placed adjacent to each other to form a row, as illustrated in FIG. 5. An array 32 may be formed by placing the dimensional solar panels 30 in a plurality of rows and columns, as illustrated in FIG. 6. This configuration may have a height that is greater than the other embodiments.

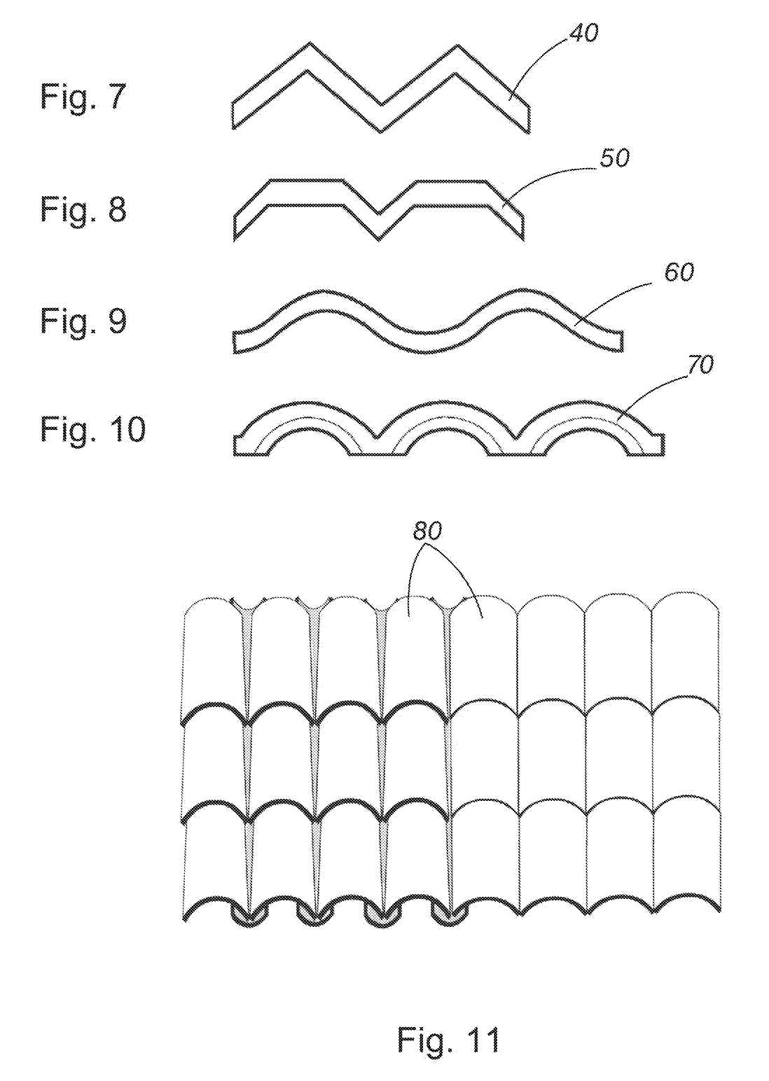

As opposed to having a curved surface as illustrated in FIG. 1, the dimensional solar panel 40 may include other configurations such as straight sections oriented at alternating upward and downward angles with respect to each other as illustrated in FIG. 7. The configuration in FIG. 7 may be modified so that the dimensional solar panels 50 have flat upper surfaces, as illustrated in FIG. 8.

The dimensional solar panel 60 may include an oscillating wave configuration as illustrated in FIG. 9. The dimensional solar panel 70 may be similar to the configuration illustrated in FIG. 1 but with a spacing provided between adjacent convex regions, as illustrated in FIG. 10.

In still another embodiment of the invention, an array of the dimensional solar panels 80 may be placed in an array having a tile roof style, as illustrated in FIG. 11. The dimensional solar panels 80 may be recessed into a cavity to appear flush with the dimensional solar panels 80, or above the surface of the dimensional solar panels 80.

It is also possible to apply a cover material over the solar panels. The cover material may substantially cover the solar panel. The cover material may have a variety of functions. One such suitable function for the cover material is to protect the solar cells from damage, such as by contact from objects. The cover material may also increase the durability of the solar panels.

The upper surface of the cover material may assume a variety of configurations. One such suitable configuration for the upper surface of the cover material is substantially flat. The upper surface may be fabricated from a relatively smooth material that enhances the potential of objects that fall on the solar panel to slide off the solar panel.

In certain embodiments, a lower surface of the cover material may substantially conform to a surface of the solar cells. In other embodiments, the lower surface of the cover material may be substantially flat.

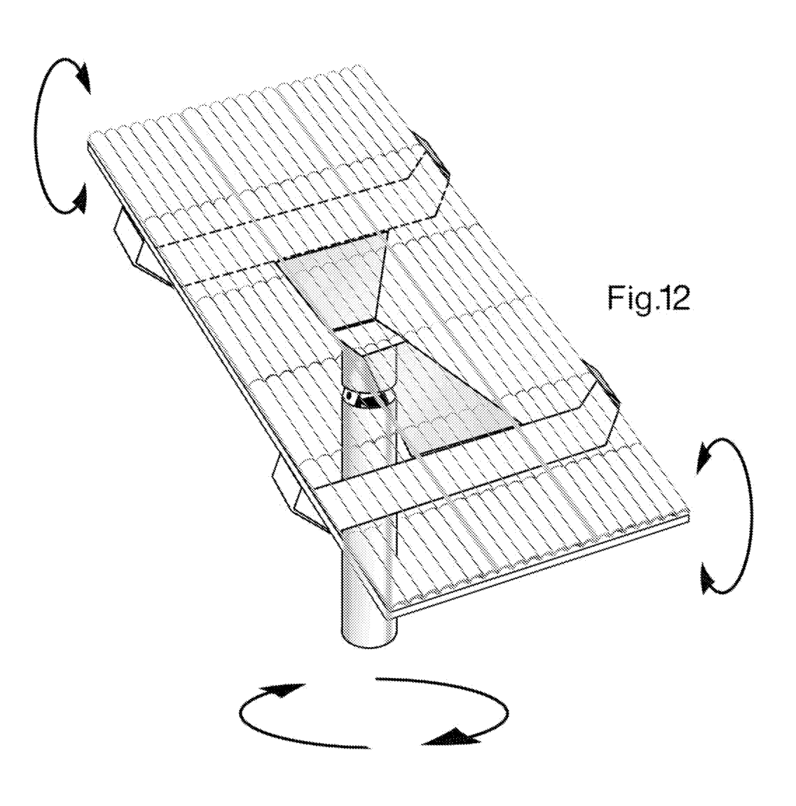

FIG. 12 shows a mounting structure of use in conjunction with the solar panels of the present invention. The mounting structure may include a support frame that is connected to a lower surface of the solar panel.

The mounting structure may also include a rotating assembly that connects the support frame to a ground surface. Depending on the location in which the solar panels are used, the rotating assembly may permit more than one degree of motion. In certain embodiments, the rotating assembly may permit pivoting of the solar panel in a direction of the upper and lower ends thereof. The rotating assembly may also permit pivoting of the solar panel in a side to side direction.

In the preceding detailed description, reference is made to the accompanying drawings, which form a part hereof, and which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The preceding detailed description, therefore, is not to be taken in a limiting sense, and the scope of the present invention is defined by the appended claims.

It is contemplated that features disclosed in this application, as well as those described in the above applications incorporated by reference, can be mixed and matched to suit particular circumstances. Various other modifications and changes will be apparent to those of ordinary skill.

1. A dimensional solar panel comprising a plurality of solar cells that are arranged in a spacing, wherein the solar panel has a convex configuration so that the solar panel comprises at least 10 percent more solar cells than a flat solar panel with a plurality of solar cells that are arranged in the spacing.

2. The dimensional solar panel of claim 1, wherein the solar panel comprises about 30 percent more solar cells than the flat solar panel.

3. The dimensional solar panel of claim 1, wherein the solar cells comprise at least one of the following configurations flexible photovoltaic, monocrystalline or single crystal silicon, multicrystalline silicon, polycrystalline silicon, amorphous silicon, cast cell components and thin film or printed plastic elements.

4. The dimensional solar panel of claim 1, wherein the solar panel comprises a central panel region and two side panel regions, wherein the central panel region and the two side panel regions are each substantially flat, wherein side panel regions are located on opposite edges of the central panel region and wherein the central panel region and the two side panel regions are arranged in a convex configuration.

5. The dimensional solar panel of claim 1, wherein the dimensional solar panel includes a plurality of convex regions.

6. The dimensional solar panel of claim 1, wherein the dimensional solar panel further includes a plurality of concave regions and wherein the convex regions and the concave regions are placed in an alternating relationship so that the dimensional solar panel has an oscillating wave configuration.

7. The dimensional solar panel of claim 1, and further comprising a cover material that substantially covers an upper surface thereof.

8. The dimensional solar panel of claim 7, wherein the cover material is fabricated from a material that is more durable than the solar cells.

9. The dimensional solar panel of claim 7, wherein an upper surface of the cover material is substantially flat.

10. The dimensional solar panel of claim 1, and further comprising a mounting assembly that mounts the dimensional solar panel with respect to a ground surface, wherein the mounting assembly allows the dimensional solar panel to be moved in more than one degree of motion with respect to the ground surface.

11. A solar energy generation system comprising a plurality of the solar panels of claim 1 that are arranged in an array having a plurality of rows and a plurality of columns.

12. The solar energy generation system of claim 11, wherein the solar panels in the array at least partially overlap.

13. A dimensional solar panel comprising a plurality of solar cells mounted on a support, wherein the support has a convex configuration so that the dimensional solar panel has at least 10 percent more solar cells than a flat solar panel having a width and a length that are approximately the same as a length and a width of the dimensional solar panel.

14. The dimensional solar panel of claim 13, wherein the solar panel comprises about 30 percent more solar cells than the flat solar panel.

15. The dimensional solar panel of claim 13, wherein the solar cells comprise at least one of the following configurations flexible photovoltaic, monocrystalline or single crystal silicon, multicrystalline silicon, polycrystalline silicon, amorphous silicon, cast cell components and thin film or printed plastic elements.

16. The dimensional solar panel of claim 13, wherein the solar panel comprises a central panel region and two side panel regions, wherein the central panel region and the two side panel regions are each substantially flat, wherein side panel regions are located on opposite edges of the central panel region and wherein the central panel region and the two side panel regions are arranged in a convex configuration.

17. The dimensional solar panel of claim 13, wherein the dimensional solar panel includes a plurality of convex regions and a plurality of concave regions, wherein the convex regions and the concave regions are placed in an alternating relationship so that the dimensional solar panel has an oscillating wave configuration.

18. The dimensional solar panel of claim 13, and further comprising a cover material that substantially covers an upper surface thereof, wherein the cover material is fabricated from a material that is more durable than the solar cells and wherein an upper surface of the cover material is substantially flat.

19. A solar energy generation system comprising a plurality of the solar panels of claim 13 that are arranged in an array having a plurality of rows and a plurality of columns.

20. The solar energy generation system of claim 19, wherein the solar panels in the array at least partially overlap.
